(19) United States
(12) Patent Application Publication
(10) Pub. No.: US 2025/0022669 A1
(43) Pub. Date: Jan. 16, 2025

(54) PROCESS FOR DETECTING DEGRADATION OF A SWITCHING DEVICE

(71) Applicant: Schneider Electric Industries SAS, Rueil Malmaison (FR)

(72) Inventors: Jean-Pierre Meley, Saint Ismier (FR); Diana El Khoury, Grenoble (FR)

(73) Assignee: Schneider Electric Industries SAS, Rueil Malmaison (FR)

(21) Appl. No.: 18/768,666

(22) Filed: Jul. 10, 2024

(30) Foreign Application Priority Data
Jul. 13, 2023 (FR) 2307587

(51) Int. Cl. H01H 1/00; H01H 1/20; H01H 50/32

(52) U.S. Cl. CPC H01H 1/0015; H01H 1/2058; H01H 50/321

(57) ABSTRACT

A process for detecting degradation of a switching device including: a mobile electrical contact; a control mechanism including: a driving element of the mobile contact, an elastic member linked to the driving element, and an unlocking member configured to release the elastic member so as to move the contact so as to open an electrical circuit; and an actuator configured to displace the unlocking member. The process includes: (i) commanding the actuator, (ii) determining the duration of time between a first instant corresponding to a predetermined position of the unlocking member and a second instant corresponding to a predetermined position of the driving member, (v) carrying out a set of successive commands of the actuator, so as to obtain a set of values of the duration of time, and (vi) determining a degradation of the unlocking member of the switching device from the evolution of the values of the set of values.

### TECHNICAL FIELD

The present invention relates to the field of switching devices for electrical equipment, for example, for low and medium voltage electrical equipment. The switching device can be a circuit breaker, for example.

### PRIOR ART

A low or medium voltage switching device can comprise one or more actuators, for example, of the electromagnetic type, for triggering the opening of an electrical circuit. To this end, the actuator can unlock a spring control mechanism, allowing a mobile electrical contact to be displaced so as to open or close the electrical circuit. In the case of a circuit breaker, the electrical circuit is opened when a fault occurs in the electrical circuit. The fault can be, for example, a short-circuit between two phases, or between one phase and earth.

When the actuator is of the electromagnetic type, it comprises a mobile magnetic core and a control coil. Under the action of an electric current flowing through the control coil, the magnetic core displaces. The magnetic core is mechanically coupled to a driving element acting on the mobile electrical contacts so as to be able to open or close the electrical circuit. Closing the circuit allows a load to be powered on.

To ensure the safety of the electrical network and of individuals, it is important to be able to check the correct operation of switching devices throughout their service life. A switching device generally experiences the effects of ageing, which can gradually degrade its electrical or mechanical functions, ultimately rendering it inoperative. It is therefore important for users to be able to monitor changes in the state of the switching device. In particular, it is desirable to be able to monitor the state of the control mechanism between the actuator and the mobile contacts, and in particular to be able to detect any degradation in this control mechanism. Users can thus intervene in order to repair or change the control mechanism at an appropriate time in the management of the electrical network.

### SUMMARY

To this end, the invention proposes a process for detecting degradation of a switching device comprising:
an electrical contact movable between a closed position of an electrical circuit and an open position of the electrical circuit;
a control mechanism comprising:
a driving element configured to displace the mobile electrical contact so as to open an electrical circuit;
an elastic member connected to the driving element;
an unlocking member configured to transition from a locking position, in which the elastic member is held in a tensioned state, to a release position, in which the elastic member is free to slacken, so as to displace the electrical contact from the closed position to the open position of the electrical circuit, or from the open position to the closed position;
an actuator configured to displace the unlocking member from the locking position to the release position,
the process comprising the following steps:
(i) commanding the actuator so as to displace the unlocking member from the locking position to the release position;
(ii) determining a first instant corresponding to a predetermined position of the unlocking member;
(iii) determining a second instant corresponding to a predetermined position of the driving element;
(iv) determining an elapsed duration between the first instant and the second instant;
(v) iterating steps (i) to (iii) for a set of successive commands of the actuator, so as to obtain a set of values of the elapsed duration between the first instant and the second instant;
(vi) determining degradation of the unlocking member of the switching device from the change in the values of the set during successive commands of the actuator.

The process for detecting degradation of the switching device is a process for detecting a change in the behaviour of the control mechanism of the switching device due to the ageing of its components. Ageing of the components includes, for example, wear, deformation, the effect of corrosion, as well as changes in the tribological properties of the components.

The elapsed duration between the first instant and the second instant corresponds to the reaction time of the unlocking member. Monitoring changes in the value of the duration, i.e., how the duration changes over the service life of the switching device, allows any changes to be monitored in the behaviour of the control mechanism of the switching device during its use.
When the unlocking device operates nominally, the values of the set do not substantially change during successive actuations of the switching device. In other words, the various values of the set are substantially constant. Conversely, gradual degradation of the control mechanism tends to cause the values to change during successive actuations, in particular to cause a fluctuation in these values. The values of the set are no longer substantially constant and fluctuate significantly. This gradual change allows degradation of the unlocking member to be detected.
The process for detecting degradation of the switching device is a process that also allows the appearance of a fault in the switching device to be anticipated.
Indeed, uncorrected degradation of the switching device can ultimately lead to the appearance of a fault, and this fault thus can be anticipated.

The features listed in the following paragraphs can be implemented independently of one another or according to any technically feasible combination:

In step (vii), the change in the values of the set can be a fluctuation in the values of the set during successive commands of the electromagnetic actuator.

According to one embodiment, the electrical contact is movable between a closed position of an electrical circuit and an open position of the electrical circuit, and slackening the elastic member displaces the electrical contact from the closed position to the open position of the electrical circuit.

The control mechanism thus allows the flow of electric current through the circuit to be interrupted.

According to another embodiment, the electrical contact is movable between an open position of an electrical circuit and a closed position of the electrical circuit, and slackening the elastic member displaces the electrical contact from the open position to the closed position of the electrical circuit.

The control mechanism thus allows a flow of electric current to be established through the circuit.

The set of values of the elapsed duration between the first instant and the second instant is obtained by a series of consecutive actuations of the switching device.

Each value of the set of values of the elapsed duration between the first instant and the second instant corresponds to a separate actuation of the switching device.

Each actuation of the switching device corresponds to a command for the actuator.

The switching device can be a circuit breaker. The switching device can be a switch.

The switching device can be an isolator.

According to one embodiment, the actuator is an electromagnetic actuator.

The electromagnetic actuator comprises an electromagnet.

The electromagnetic actuator comprises a control coil and a magnetic core configured to displace under the action of a magnetic field created by a flow of electric current through the control coil.

The magnetic core can move translationally, for example.

The unlocking member is connected to a magnetic core of the electromagnetic actuator.

According to another embodiment, the actuator comprises a push-button that can be manually activated by an operator.

The unlocking member comprises a position indicator.

The position indicator provides a two-level signal.

The position indicator is a contactor with two electrical states.

The predetermined position of the unlocking member for determining the first instant can be a balanced position of the unlocking member.

The predetermined position of the unlocking member for determining the first instant can be a transient position of the unlocking member.

The predetermined position of the driving element for determining the second instant can be a transient position of the driving element.

The elastic member is configured to apply a driving force to the electrical contact.

The elastic member can be a spring, for example, a spiral spring or a helical spring.

The driving member can be free to rotate.

The driving element can be connected to the mobile contact by a connecting rod.

Measuring a current flowing through the electromagnetic actuator is understood to mean measuring the intensity of the electric current flowing through the electromagnetic actuator.

The current flowing through the electromagnetic actuator can be detected by a sensor for measuring the current flowing through the electromagnetic actuator.

The current flowing through the electromagnetic actuator can be sampled, for example, with a sampling frequency ranging between 1 kHz and 100 kHz.

The actuator is configured to trigger displacement of the mobile electrical contact in order to open or close the electrical circuit.

When the switching device is a circuit breaker, the electromagnetic actuator is configured to trigger opening of the electrical circuit if a fault is present on the electrical circuit.

According to one embodiment of the proposed detection process, wherein the actuator is an electromagnetic actuator, the process comprises the following sub-steps:
measuring a current flowing through the electromagnetic actuator when the switching device is actuated;
determining the first instant corresponding to a predetermined position of the unlocking member from the temporal variations in the measured current.

The proposed process thus does not require the installation of any additional sensor, such as an electrical contact displacement sensor or a displacement sensor for an element of the actuating mechanism.

The proposed process includes a sub-step of determining temporal variations in the measured current.

The electromagnetic actuator comprises a control coil and a magnetic core configured to displace under the action of a magnetic field created by a flow of electric current through the control coil.

The predetermined position of the unlocking member corresponding to the first instant is a position of maximum displacement of the magnetic core.

According to one aspect of the detection process, the first instant corresponding to a predetermined position of the unlocking member is an instant corresponding to a local minimum value of the electric current flowing through the electromagnetic actuator.

The first instant can be determined from the temporal change in the intensity of the current flowing through the control coil, and coincides with the instant when the current passes through a local minimum value.

According to another embodiment of the proposed detection process, wherein the actuator comprises a push-button that can be manually activated by an operator and wherein the unlocking member comprises a position indicator, the process comprises the following sub-steps:
measuring an electrical signal from the position indicator;
determining the first instant corresponding to a predetermined position of the unlocking member from temporal variations in the electrical signal from the position indicator.

The instant corresponds to a change in the electrical state of the position indicator.

The instant is a temporal reference indicating that the action exerted on the push-button has definitely been transmitted to the unlocking member.

According to one embodiment of the detection process, the predetermined position of the driving element corresponding to the second instant is an intermediate displacement position of the driving element. The intermediate displacement position lies between a first end position, in which the mobile electrical contact is in the closed position, and a second end position, in which the mobile electrical contact is in the open position.

An angular displacement stroke of the driving element ranges between 40° and 60°, for example.

According to one embodiment of the detection process, a displacement stroke of the driving element between the first end position and the predetermined position corresponding to the second instant ranges between 5% and 15% of a total displacement stroke of the driving element.

The initial part of the displacement stroke of the driving element is thus used to determine the second instant acting as a reference. The detection sensitivity of the proposed process is thus improved.

The detection process can comprise the following sub-steps:
measuring a position of the driving element when the switching device is actuated;
determining the second instant corresponding to the predetermined position of the driving element from the measured position of the driving element.

According to one embodiment of the proposed detection process:
the control mechanism comprises a position sensor configured to detect a magnetic field;
the driving element comprises a plurality of magnetic elements configured to successively pass in front of the position sensor during a displacement stroke of the driving element.

The magnetic elements can be permanent magnets.

The position sensor can be a Hall effect sensor.

The magnetic elements are disposed, for example, on part of a periphery of the driving element.

The magnetic elements can be disposed in a plane perpendicular to an axis of rotation of the driving element.

The magnetic elements can be identical.

An angular spacing between two consecutive magnetic elements can be constant.

For example, the driving element comprises four magnetic elements.

According to one embodiment, the unlocking member comprises a freely rotatable half-moon.

The half-moon is actuated by the magnetic core of the electromagnetic actuator.

The unlocking member can comprise an intermediate lever comprising a first portion configured to engage with the half-moon and comprising a second portion configured to engage with the driving element.

According to one embodiment, the detection process comprises the following sub-step:
computing a value of a statistical parameter representing a fluctuation in the values of the set of values of the elapsed duration between the first instant and the second instant;
determining degradation of the unlocking member from the computed value of the statistical parameter.

According to one embodiment of the detection process, the statistical parameter representing a fluctuation in the values of the set of values of the elapsed duration between the first instant and the second instant includes a difference between:
a current value of the elapsed duration between the first instant and the second instant, determined for a current actuation of the switching device; and
an average value of the values of the elapsed duration between the first instant and the second instant obtained for a predetermined number of actuations preceding the current actuation of the switching device.

The average value can be a sliding average computed from the values corresponding to the actuations preceding the current actuation, and comprising a number of values that is equal to the predetermined number of actuations.

According to one embodiment of the detection process, the statistical parameter representing a fluctuation in the values of the set of values of the elapsed duration between the first instant and the second instant comprises a standard deviation of the values of the elapsed duration between the first instant and the second instant determined for a set of actuations of the switching device carried out under reference conditions corresponding to a new state of the circuit breaker.

The set of actuations of the switching device carried out under reference conditions comprises, for example, 20 successive actuations of the switching device.

The proposed process thus comprises a calibration phase allowing the nominal variations in the value of the elapsed duration between the first instant and the second instant when actuating the switching device to be quantified. These nominal variations correspond to the variations observed in a reference state in which the switching device exhibits neither assembly faults nor degradation due to wear.

The reference state corresponds to a new state of the switching device, for example.

The proposed process comprises a measurement phase, in which the variations in the value of the elapsed duration between the first instant and the second instant are analysed.

The measurement phase follows the calibration phase.

The measurement phase is carried out throughout the operating service life of the switching device.

According to one embodiment of the proposed detection process, the statistical parameter representing a fluctuation in the elapsed duration between the first instant and the second instant is equal to the ratio of:
the difference between a current value of the elapsed duration between the first instant and the second instant and the average value of the values of the elapsed duration between the first instant and the second instant obtained for a predetermined number of actuations preceding the current actuation; and
the standard deviation of the values of the elapsed duration between the first instant and the second instant determined for a set of actuations of the switching device carried out under reference conditions corresponding to a new state of the switching device.

The proposed statistical parameter allows reliable detection of any degradation of the unlocking member of the switching device, while being simple to implement. In particular, the necessary computations can be easily carried out in real time, which allows rapid degradation detection.

The statistical parameter representing a fluctuation in the elapsed duration between the first instant and the second instant thus can be equal to:

$$\\ \begin{matrix}P ( i ) = \frac{{D}_{i} - \frac{{\sum }_{j = i - M}^{j = i - 1} {D}_{j}}{M}}{\sqrt{{\sum }_{j = 1}^{N} {( \frac{{D}_{j} - \frac{{\sum }_{j = 1}^{j = N} {D}_{j}}{K}}{K} )}^{2}}} & [ Math . 1 ]\end{matrix}$$

With Dᵢ being the determined value of the duration D for an actuation of rank i, P(i) being the computed value of the statistical parameter P for the actuation of rank i, M being the number of actuations taken into account to determine an average value, K being a number of actuations carried out under reference conditions corresponding to a new state of the switching device.

According to one aspect of the proposed detection process, degradation of the unlocking member is determined when the absolute value of the statistical parameter representing a fluctuation in the elapsed duration between the first instant and the second instant is greater than a first positive predetermined threshold.

The value selected for the first predetermined threshold allows the sensitivity of the proposed detection process to be adjusted.

The first predetermined threshold ranges between 2 and 3, for example.

According to one embodiment of the detection process, the degradation of the unlocking member is classified as a first type of degradation, called minor degradation, when the absolute value of the statistical parameter representing a fluctuation in the elapsed duration between the first instant and the second instant is greater than a first positive predetermined threshold and less than a second positive predetermined threshold.

The second predetermined threshold ranges between 4 and 5, for example.

According to one embodiment of the detection process, the degradation of the unlocking member is classified as a second type of degradation, called major degradation, when the criterion representing a fluctuation in the elapsed duration between the first instant and the second instant is greater than the second predetermined threshold.

The statistical parameter P that is used thus allows the degradation to be quantified, and not merely the presence or absence of degradation.

The detection process can comprise a step of transmitting a warning signal in the event that degradation of the unlocking member has been determined.

The transmitted warning signal allows users to schedule and to carry out a maintenance or replacement operation for the switching device.

A warning signal is not transmitted when no degradation has been determined. In other words, no warning is transmitted when the proposed process indicates that the unlocking member is degradation free.

The invention also relates to a switching device comprising:
an electrical contact movable between a closed position of an electrical circuit and an open position of the electrical circuit;
a control mechanism comprising:
a driving element configured to displace the mobile electrical contact so as to open an electrical circuit;
an elastic member connected to the driving element;
an unlocking member configured to transition from a locking position, in which the elastic member is held in a tensioned state, to a release position, in which the elastic member is free to slacken, so as to displace the electrical contact from the closed position to the open position of the electrical circuit;
an actuator configured to displace the unlocking member from the locking position to the release position;
an electronic control unit configured to implement the degradation detection process as described above.

The switching device can be a circuit breaker, or a switch or an isolator.

### BRIEF DESCRIPTION OF THE DRAWINGS

Further features, details and advantages will become apparent from reading the following detailed description, and with reference to the appended drawings, in which:

FIG. 1 is a schematic view of an electrical circuit equipped with a switching device, with the electrical circuit being in the closed position;

FIG. 2 is a schematic view of an electrical circuit equipped with a switching device, with the electrical circuit being in the open position;

FIG. 3 is a schematic view of the control mechanism of a switching device according to a first embodiment, with the electrical circuit being in the closed position;

FIG. 4 is a schematic view of the control mechanism of the switching device of FIG. 3, with the electrical circuit being in the open position,

FIG. 5 illustrates the temporal change in several operating parameters of the switching device of FIGS. 3 and 4, when said switching device is actuated;

FIG. 6 is a temporal diagram illustrating the process according to the invention;

FIG. 7 is a block diagram illustrating various steps of the process according to the invention;

FIG. 8 is a schematic view of the control mechanism of a switching device according to a second embodiment, with the electrical circuit being in the closed position;

FIG. 9 is a schematic view of the control mechanism of the switching device of FIG. 7, with the electrical circuit being in the open position.

### DESCRIPTION OF THE EMBODIMENTS

In order to make the figures easier to read, the various elements are not necessarily shown to scale. Throughout these figures, identical elements use the same reference signs. Some elements or parameters can be indexed, i.e., for example, referred to as first element or second element, or even as first parameter and second parameter, etc. The purpose of this indexing is to differentiate between similar, but not identical, elements or parameters. This indexing does not imply that one element or parameter has priority over another, and the designations can be interchanged. When it is specified that a sub-system contains a given element, this does not exclude the presence of other elements in this sub-system. Similarly, when it is specified that a sub-system comprises a given element, it is understood that the sub-system comprises at least this element.

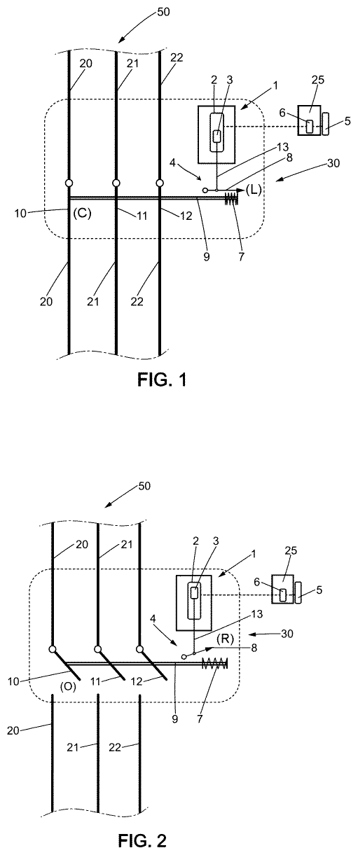

FIG. 1 schematically shows an electrical circuit 50. The electrical circuit 50 comprises three electrical conductors 20, 21, 22, with each conductor corresponding to a phase of a three-phase medium voltage network.

The electrical circuit 50 comprises a switching device 30.

The switching device 30 can be a circuit breaker. As an alternative embodiment, the switching device 30 can be a switch. According to another example of an application, the switching device 30 can be an isolator.

FIG. 1 and FIG. 2 respectively schematically illustrate two states of the switching device 30.

The switching device 30 comprises an electrical contact 10 movable between a closed position F of an electrical circuit 50 and an open position O of the electrical circuit 50.

The switching device 30 also comprises a control mechanism 4 comprising:
a driving element 9 configured to displace the mobile electrical contact 10 so as to open an electrical circuit 50;
an elastic member 7 connected to the driving element 9;
an unlocking member 8 configured to transition from a locking position V, in which the elastic member 7 is held in a tensioned state, to a release position L, in which the elastic member 7 is free to slacken, so as to displace the electrical contact 10 from the closed position F to the open position O of the electrical circuit 50.
   The switching device 30 further comprises an actuator 1 configured to displace the unlocking member 8 from the locking position V to the release position L.
   The switching device 30 also comprises an electronic control unit 25 configured to implement the degradation detection process that will be described in detail hereafter.

The elastic member 7 is configured to apply a driving force to the electrical contact 10.

The elastic member 7 can be a spring, for example, a spiral spring or a helical spring.

The actuator 1 is configured to trigger a displacement of the mobile electrical contact 10 in order to open or close the electrical circuit 50.

Indeed, the actuator 1 allows the control mechanism 4 to be unlocked in order to displace the mobile contact 10 and thus open or close the electrical circuit 50.

In FIG. 1, the mobile contacts 10, 11, 12 are in the closed position, i.e., an electric current can flow through the electrical circuit 50. Reference sign F indicates the closed position of the mobile contact 10.

The elastic member 7 is in the tensioned state. The elastic member 7 is held in the tensioned state by the unlocking member 8. The driving element 9 is blocked by the unlocking member 8.

The electrical circuit 50 is opened as follows:

Under the action of the actuator 1, the unlocking member 8 is displaced to a release position L, in which the driving element 9 is no longer blocked by the unlocking member 8. The driving element 9 can displace under the action of the driving force applied by the elastic member 7, which was in a tensioned state and is free to slacken. The driving element 9 thus displaces the electrical contact 10 from the closed position F to the open position O of the electrical circuit 50.
The three mobile contacts 10, 11, 12 are mechanically coupled, so that the three contacts 10, 11, 12 jointly transition to the open position when the control mechanism 4 is unlocked.
FIG. 2 schematically shows the position of the various elements once the mobile contacts 10, 11, 12 have been displaced to the open position of the electrical circuit 50.

According to the embodiment illustrated in FIG. 1 and FIG. 2, the actuator 1 is an electromagnetic actuator.

The electromagnetic actuator 1 comprises an electromagnet.

The electromagnetic actuator 1 comprises a control coil 2 and a magnetic core 3 configured to displace under the action of a magnetic field created by a flow of electric current through the control coil 2.
The magnetic core 3 can move translationally, for example.

The unlocking member 8 is connected to the magnetic core 3 of the electromagnetic actuator 1.

A displacement of the magnetic core 3 of the electromagnetic actuator 1 therefore causes a displacement of the unlocking member 8.

When the switching device 30 is a circuit breaker, the electromagnetic actuator 1 is configured to trigger opening of the electrical circuit 50 if a fault is present on the electrical circuit 50.

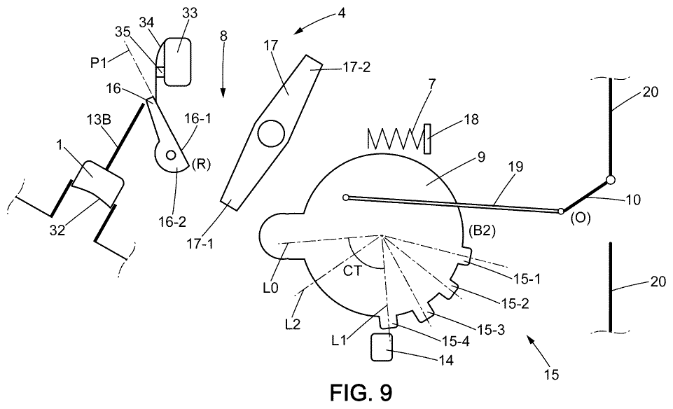

According to another embodiment, illustrated in FIGS. 8 and 9, the actuator 1 comprises a push-button 32 that can be manually operated by an operator. When the operator wishes to trigger the opening of the electrical circuit 50, the operator presses the push-button 32, which is mechanically connected to the unlocking member 8. The unlocking member 8 is thus unlocked by the action of the operator on the push-button 32.

In this embodiment, the unlocking member 8 comprises a position indicator 33.

The proposed process is intended to detect degradation of the switching device 30, i.e., to detect a change in the behaviour of the control mechanism 4 of the switching device 30, and in particular of the unlocking member 8, due to ageing of its components. Ageing of components includes, for example, wear, deformation, changes in magnetic performance, as well as changes in the tribological properties of components.

A process is thus proposed for detecting degradation of a switching device 30 comprising:
an electrical contact 10 movable between a closed position F of an electrical circuit 50 and an open position O of the electrical circuit 50;
a control mechanism 4 comprising:
a driving element 9 configured to displace the mobile electrical contact 10 so as to open an electrical circuit 50;
an elastic member 7 connected to the driving element 9;
an unlocking member 8 configured to transition from a locking position V, in which the elastic member 7 is held in a tensioned state, to a release position L, in which the elastic member 7 is free to slacken, so as to displace the electrical contact 10 from the closed position F to the open position O of the electrical circuit 50, or from the open position O to the closed position F;
an actuator 1 configured to displace the unlocking member 8 from the locking position V to the release position L,
   the process comprising the following steps:
(i) commanding the actuator 1;
(ii) determining a first instant t1 corresponding to a predetermined position P1 of the unlocking member 8;
(iii) determining a second instant t2 corresponding to a predetermined position P2 of the driving element 9;
(iv) determining an elapsed duration D between the first instant t1 and the second instant t2;
(v) iterating steps (i) to (iii) for a set of successive commands of the actuator 1, so as to obtain a set E of values of the elapsed duration D between the first instant t1 and the second instant t2;
(vi) determining degradation of the unlocking member 8 of the switching device 30 from the change in the values of the set E during successive commands of the actuator 1.

The elapsed duration D between the first instant t1 and the second instant t2 corresponds to a reaction time of the unlocking member 8. Monitoring changes in the value of the duration D, i.e., how the duration D changes over the service life of the switching device 30, allows any changes to be monitored in the behaviour of the unlocking member of the control mechanism 4 during its use.

When the unlocking member of the control mechanism 4 operates nominally, the values of the set E do not substantially change during successive actuations of the switching device 30. In other words, the various values of the set E are substantially constant. Conversely, gradual degradation of the unlocking member of the control mechanism 4 during the service life of the switching device 30 tends to cause the values of the set E to change during successive actuations, in particular to cause a fluctuation in these values. The values of the set E are thus no longer substantially constant and fluctuate significantly. This gradual change allows degradation of the unlocking member 8 of the control mechanism 4 to be detected.
The process for detecting degradation of the switching device 30 is a process that also allows a fault in the switching device 30 to be detected.
Indeed, uncorrected degradation of the switching device 30 can ultimately lead to the appearance of a fault, and this fault also can be detected.

The opening movement of the mobile electrical contact and the closing movement can be carried out in a similar manner.

According to one embodiment, the electrical contact 10 is movable between a closed position F of the electrical circuit 50 and an open position O of the electrical circuit 50; and
slackening the elastic member 7 displaces the electrical contact 10 from the closed position F to the open position O of the electrical circuit 50.
The control mechanism 4 thus allows the flow of electric current through the circuit 50 to be interrupted.

According to another embodiment, the electrical contact 10 is movable between an open position O of an electrical circuit 50 and a closed position F of the electrical circuit 50; and

slackening of the elastic member 7 displaces the electrical contact 10 from the open position O to the closed position F of the electrical circuit 50.
The control mechanism 4 thus allows a flow of electric current to be established through the circuit 50.

The set E of values of the elapsed duration D between the first instant t1 and the second instant t2 is obtained by a series of consecutive actuations of the switching device 30.

Each value of the set E of values of the elapsed duration D between the first instant t1 and the second instant t2 corresponds to a separate actuation of the switching device 30.

Each actuation of the switching device 30 corresponds to a command from the actuator 1. ‘Actuation of the switching device 30’ is understood to mean the transition of the electrical contact 10 from the closed position F of the electrical circuit 50 to the open position O of the electrical circuit 50 in response to a command from the actuator 1.

When the actuator 1 is an electromagnetic actuator, actuation of the switching device 30 is achieved by causing current to flow through the control coil 2.

When the actuator 1 is a push-button, actuation of the switching device 30 is achieved by the operator pressing the push-button.

The predetermined position P1 of the unlocking member 8 is a first characteristic position for defining a first temporal reference for characterising the operation of the control mechanism 4.

The predetermined position P2 of the driving element 9 is a second characteristic position for defining a second temporal reference for characterising the operation of the control mechanism 4.
More specifically, the duration separating these two temporal references can be a parameter for determining degradation of the control mechanism 4 of the switching device 30.

According to the illustrated example, the predetermined position P1 of the unlocking member 8 for determining the first instant t1 can be a balanced position of the unlocking member 8.

In other words, the speed of the unlocking member 8 is zero when the unlocking member 8 is in the predetermined position P1 for determining the first instant t1.

According to one embodiment, not shown, the predetermined position P1 of the unlocking member 8 for determining the first instant t1 can be a transient position of the unlocking member 8.

In this case, the speed of the unlocking member 8 is non-zero when the unlocking member 8 is in the predetermined position P1 for determining the first instant t1. The first instant t1 corresponds to the unlocking member 8 passing through the first position P1.

The predetermined position P2 of the driving element 9 for determining the second instant t2 can be a transient position of the driving element 9.

In other words, the speed of the driving element 9 is non-zero when the driving element 9 is in the predetermined position P2 for determining the second instant t2. The second instant t2 corresponds to the driving element 9 passing through the second position P2.

The elapsed duration D between the first instant t1 and the second instant t2 corresponds to the duration separating the first instant t1 and the second instant t2.

The manner of determining the first instant t1 depends on the type of actuator 1.

When the actuator 1 is an electromagnetic actuator, determining the first instant t1 is based on a measurement of the current in the electromagnetic actuator 1.

‘Measuring a current C flowing through the electromagnetic actuator 1’ is understood to mean measuring the intensity of the electric current flowing through the electromagnetic actuator 1.

The current C flowing through the electromagnetic actuator 1 can be detected by a sensor 6 for measuring the current flowing through the electromagnetic actuator 1.
The current C flowing through the electromagnetic actuator 1 can be sampled, for example, with a sampling frequency ranging between 1 kHz and 100 kHz.

In the embodiment in which the actuator 1 is an electromagnetic actuator, the process comprises the following sub-steps:
measuring a current C flowing through the electromagnetic actuator 1 when the switching device 30 is actuated;
determining the first instant t1 corresponding to a predetermined position P1 of the unlocking member 8 from the temporal variations in the measured current C.

The proposed process thus does not require the installation of any additional sensor, such as an electrical contact displacement sensor or a displacement sensor for an element of the actuating mechanism.

The proposed process thus can include a sub-step of determining temporal variations in the measured current C.

The electromagnetic actuator 1 comprises a control coil 2 and a magnetic core 3 configured to displace under the action of a magnetic field created by a flow of electric current through the control coil 2.

The predetermined position P1 of the unlocking member 8 corresponding to the first instant t1 is a position of maximum displacement of the magnetic core 3.

In other words, the first instant t1 corresponds to an instant when the magnetic core 3 reaches its position of maximum displacement.

The first instant t1 corresponding to a predetermined position P1 of the unlocking member 8 is an instant corresponding to a local minimum value of the electric current flowing through the electromagnetic actuator 1.

The first instant t1 thus can be determined from the temporal change in the intensity of the current flowing through the control coil 2, and coincides with the instant when the current passes through a local minimum value.

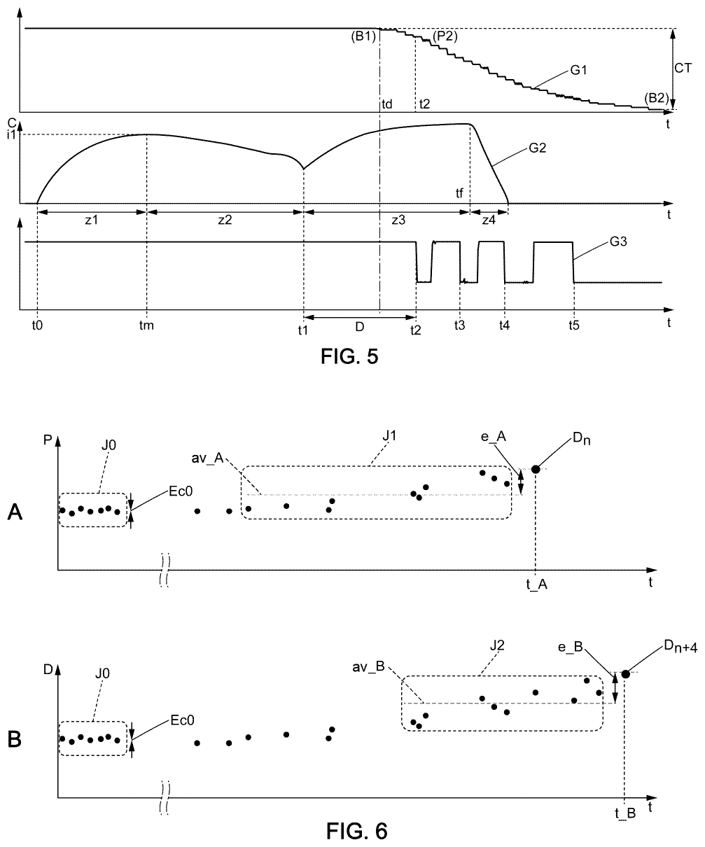

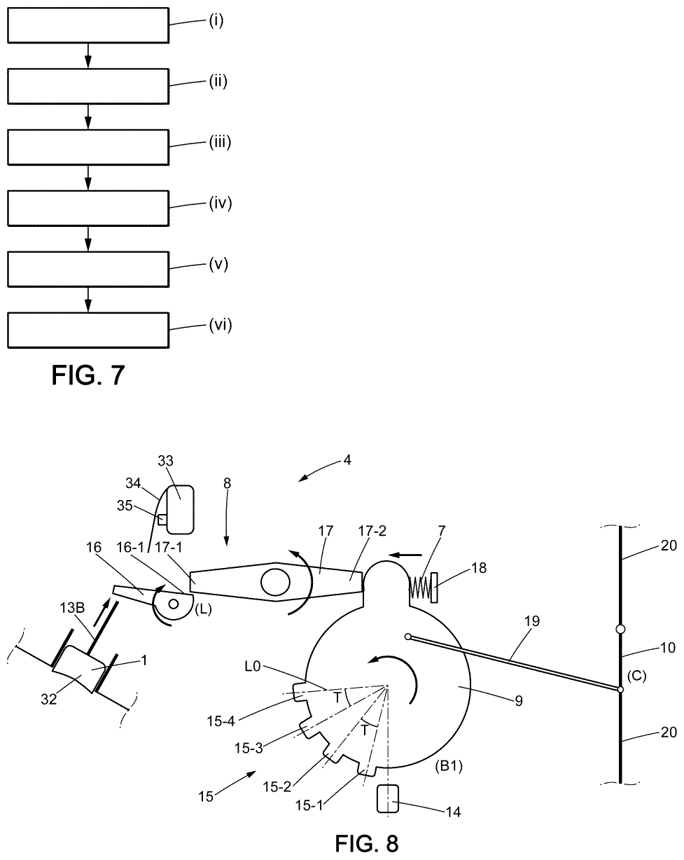

FIG. 5 illustrates the change in several parameters when the switching device is actuated. In FIG. 5, the curve G2 illustrates the temporal change in the electric current in the electromagnetic actuator 1 when it is controlled. The curve G2 comprises a first continuously increasing portion z1, a second continuously decreasing portion z2, with the second portion z2 following the first portion z1, a third continuously increasing portion z3, with the third portion z3 following the second portion z2. The instant t1 corresponding to the local minimum of the current corresponds to the instant separating the third portion z3 from the second portion z2.

The control of the electromagnet is deactivated at the instant tf, and the portion z4 corresponds to a phase in which the current decreases until it reaches zero. The current remains zero until the next activation, or control, of the electromagnet.

A local maximum value i1 of the current is obtained for an instant tm ranging between an instant to corresponding to the start of the flow of electric current through the electromagnetic actuator 1 and an instant t1 corresponding to a local minimum of the electric current flowing through the electromagnetic actuator 1.

The local maximum value i1 of the current is the value of the current obtained when transitioning from the first portion z1 to the second portion z2.
The reduction in current between the instant tm and the instant t1 is associated with the change in the gap between the mobile parts and the fixed parts. Once the gap no longer changes, the current starts to increase again, which corresponds to the portion z3 of the curve G2.
From the instant t1, the electromagnetic actuator 1 has reached its maximum displacement stroke and the position of the magnetic core 3 no longer changes. However, electrical control is maintained until the instant tf, in order to provide a retention force.

When the actuator 1 is a purely mechanical actuator of the push-button type, determining the first instant t1 is based on the signal from a position indicator, also called position sensor.

The unlocking member 8 thus comprises a position indicator 33.

The position indicator 33 can provide a two-level signal.
The position indicator 33 is a contactor with two electrical states.
In other words, the signal from the position indicator 33 switches from a first level to a second level when the locking member reaches a certain threshold position.

Thus, in the proposed embodiment of the detection process, wherein the actuator 1 comprises a push-button 32 that can be manually activated by an operator and wherein the unlocking member 8 comprises a position indicator 33, the process comprises the following sub-steps:
measuring an electrical signal from the position indicator 33;
determining the first instant t1 corresponding to a predetermined position P1 of the unlocking member 8 from temporal variations of the electrical signal from the position indicator 33.

The instant t1 corresponds to a change in the electrical state of the position indicator 33.

The instant t1 is a temporal reference indicating that the action exerted on the push-button by the operator has indeed been transmitted to the unlocking member 8.

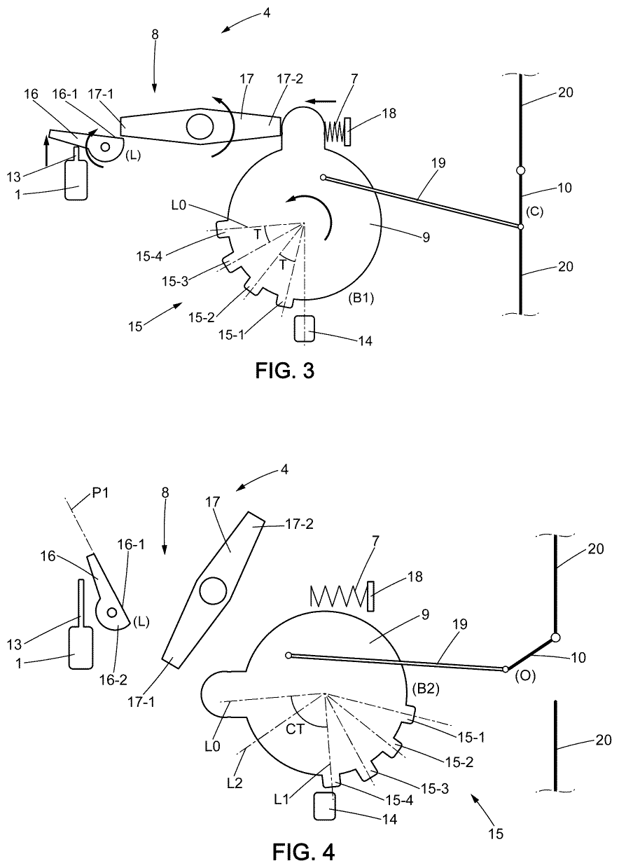

FIG. 3 and FIG. 4 illustrate an embodiment of the control mechanism 4 of the switching device 30, in which the actuator 1 is an electromagnetic actuator.

In order to simplify the figure, the elastic member 7 is shown in the form of a helical spring. The elastic member 7 also can be a spiral spring.

In FIG. 3, the unlocking member 8 is in the locking position V and the spring 7 is held in a compressed state. One end of the spring 7 exerts a force on a fixed stop 18, the other end of the spring exerts a force on the driving element 9.

The driving element 9 is free to rotate in this case. The driving element 9 is connected to the mobile contact 10 by a connecting rod 19.

The connecting rod 19 is rigid. The connecting rod 19 is pivotably connected to the driving element 9.
The connecting rod 19 is pivotably connected to the mobile contact 10.

The unlocking member 8 comprises a freely rotatable half-moon 16. The half-moon 16 assumes the general shape of a half-cylinder, and comprises a flat surface 16-1 extending parallel to the axis of the half-cylinder.

The half-moon 16 is actuated by the magnetic core 3 of the electromagnetic actuator 1.
‘Actuated’ is understood to mean that the half-moon 16 can pivot in response to the displacement of the magnetic core 3.
The electromagnetic actuator 1 comprises a connecting element 13 connecting the mobile magnetic core 3 and the half-moon 16.

The unlocking member 8 also comprises an intermediate lever 17 comprising a first portion 17-1 configured to engage with the half-moon 16 and comprising a second portion 17-2 configured to engage with the driving element 9.

In FIG. 3, where the unlocking member 8 is in the locking position V, the driving force of the elastic member 7 applied to the driving element 9 is transmitted to the intermediate lever 17 of the unlocking member 8. The half-moon 16 is in the locking position, and blocks the rotation of the intermediate lever 17 because the first portion 17-1 of the intermediate lever 17 interferes with the surface 16-1 of the half-moon 16. The second portion 17-2 blocks the driving element 9, which is thus held in place. The spring 7 is kept compressed between the driving element 9 and the fixed stop 18.

When the half-moon 16 leaves its locking position, the first portion 17-1 is no longer held and the force applied to the second portion 17-2 causes the intermediate lever 17 to pivot. The intermediate lever 17 can thus pivot under the action of the driving force of the elastic member 7. The driving element 9 can thus displace under the action of the driving force of the elastic member 7. The connecting rod 19, which is rigidly connected to the driving element 9, pivots the mobile contact 10.

In FIG. 4, the unlocking member 8 is in the release position L. The spring 7 is in the slackened state, after having pivoted the driving element 9 and thus being displaced, the mobile electrical contact 10 is in the open position O.

In FIG. 4, the half-moon 16 of the unlocking member 8 is shown in the position P1 used to define the first temporal reference t1.

According to the illustrated embodiment, the predetermined position of the driving element 9 corresponding to the second instant t2 is an intermediate displacement position of the driving element 9. The intermediate displacement position lies between a first end position B1, in which the mobile electrical contact 10 is in the closed position F, and a second end position B2, in which the mobile electrical contact 10 is in the open position O.

FIG. 3 schematically shows the first end position B1 and FIG. 4 schematically shows the second end position B2.

According to the illustrated example, a displacement stroke of the driving element 9 between the first end position B1 and the predetermined position P2 corresponding to the second instant t2 ranges between 5% and 15% of a total displacement stroke CT of the driving element 9.

The initial part of the displacement stroke of the driving element 9 is thus used to determine the second instant acting as a reference. The detection sensitivity of the proposed process is thus improved.

The total displacement stroke CT is the distance between the first end position B1 and the second end position B2 of the driving element 9.

In the case whereby the driving element 9 is free to rotate, the total displacement stroke CT is an angular spacing.

An angular displacement stroke CT of the driving element 9 ranges between 40° and 60°, for example.

Reference sign L0 denotes a reference indicating the initial position B1 of the driving element 9, and reference sign L1 denotes the position of this reference following a complete rotation of the driving element 9, when said driving element is in position B2. The difference between L0 and L1 indicates the rotation stroke CT.
Reference sign L2 denotes the position of the reference L0 when the driving element 9 is in the predetermined position P2, corresponding to the second instant t2.

The detection process can comprise the following sub-steps:
measuring a position of the driving element 9 when the switching device 30 is actuated;
determining the second instant t2 corresponding to the predetermined position P2 of the driving element 9 from the measured position of the driving element 9.

According to the embodiment illustrated herein:
the control mechanism 4 comprises a position sensor 14 configured to detect a magnetic field;
the driving element 9 comprises a plurality of magnetic elements 15 configured to successively pass in front of the position sensor 14 during a displacement stroke of the driving element 9.

When the driving element 9 transitions from the first end position B1, in which the mobile electrical contact 10 is in the closed position F, to a second end position B2, in which the mobile electrical contact 10 is in the open position O, the passage of a magnetic element 15 in front of the position sensor 14 generates a change in the electrical state of the position sensor 14. When this magnetic element 15 moves away from the sensor 14, the position sensor 15 returns to the initial electrical state. The rotation of the driving element 9 therefore generates a signal comprising a series of slots, with each slot corresponding to a separate magnetic element 15.

The magnetic elements 15 can be permanent magnets.
The position sensor 14 can be a Hall effect sensor.

The magnetic elements 15 are disposed on part of a periphery of the driving element 9.

The magnetic elements 15 in this case are disposed in a plane perpendicular to an axis of rotation of the driving element 9.
The magnetic elements 15 are identical in the illustrated example. The magnetic elements 15 also can be different.
An angular spacing T between two consecutive magnetic elements 15 is constant in this case. The magnetic elements also can be installed with an angular spacing between two consecutive magnetic elements 15 that is not from one magnetic element to another.

In the illustrated example, the driving element 9 comprises four magnetic elements 15. The four magnetic elements 15 are permanent magnets.

In FIG. 3 and FIG. 4, the 4 permanent magnets are denoted using reference signs 15-1, 15-2, 15-3, 15-4.
Of course, a different number of magnetic elements can be used.

In FIG. 5, the curve G3 illustrates the signal supplied by the position sensor 14 during the displacement of the driving element 9.

The instant t2 corresponds to the start of the passage of the first magnet 15-1 in front of the position sensor 14.
The instant t3 corresponds to the start of the passage of the second magnet 15-2 in front of the position sensor 14.
Similarly, the instant t4 corresponds to the start of the passage of the third magnet 15-3 and the instant t5 corresponds to the start of the passage of the fourth magnet 15-4.
The duration between the passage of two consecutive magnets is not constant because the speed of displacement is not constant.
In FIG. 5, the curve G1 indicates the signal delivered by a high-resolution position sensor.
In other words, this sensor delivers a substantially continuous signal and not a discrete signal. This sensor has been fitted solely by way of an experiment for the purposes of validating the proposed process, and does not form part of the switching device 30 when said switching device is used nominally. Therefore, the signal from the curve G1 is not used in the proposed process.
Up until the instant td, the signal is constant, which indicates that the driving element 9 is stationary. The driving element 9 starts to pivot at the instant indicated by td.
The instant t2 at which the position sensor 14 changes electrical state due to the passage of the magnet 15-1 is later than the instant td due to the displacement stroke required for the magnet 15-1 to be in a position opposite the position sensor 14.

As illustrated in FIG. 5, the predetermined position of the driving element 9 defining the second instant t2 corresponds to the position of the passage of the first magnet 15-1 in front of the position sensor 14.

The predetermined position P1 of the unlocking member 8 defining the first instant t1 is the end of pivoting position of the half-moon 16.
The time shift between the instant t1 and the instant t2 defines a duration D.

FIG. 8 and FIG. 9 illustrate an embodiment of the control mechanism 4 of the switching device 30, in which the actuator 1 is a mechanical actuator of the push-button type.

This embodiment differs from that of FIGS. 3 and 4 in terms of the nature of the actuator 1 and the presence of the position indicator 33.

The push-button 32 is connected to the half-moon 16 by a connecting element 13B. For example, the push-button 32 is rigidly connected to a connecting element 13B connected to the half-moon 16.
This connecting element 13B can displace the half-moon 16 in a similar way to that described within the scope of the embodiment with an electromagnetic actuator, shown in FIGS. 3 and 4.

The instant t1 is determined from the electrical signal delivered by the position indicator 33. The position indicator 33 comprises a pivoting tab 34 held at a distance from a contactor 35 by a spring, not shown.

When the half-moon 16 is at a distance from the pivoting tab 34, as is the case in FIG. 8, the tab itself is at a distance from the contactor 35, which is in the ‘released’ state. The position indicator 33 delivers a first signal level.
Once the half-moon 16 has pivoted sufficiently, it displaces the pivoting tab 34, which presses on the contactor 35 and causes it to leave the released state.
The position indicator 33 then delivers a second signal level.
The instant corresponding to a transition between the first signal level and the second signal level allows the first instant t1 to be determined.
In this embodiment, the remainder of the control mechanism 4 is identical to the embodiment of FIGS. 3 and 4, and the second instant t2 is determined in the same way.

The determined duration D is the physical parameter on which the process for detecting degradation of the control mechanism 4 is based.

Statistical processing is applied to this physical parameter.

The detection process thus comprises the following sub-step:
computing a value of a statistical parameter P representing a fluctuation in the values of the set E of values of the elapsed duration D between the first instant t1 and the second instant t2;
determining degradation of the unlocking member 8 from the computed value of the statistical parameter P.

According to one embodiment of the detection process, the statistical parameter P representing a fluctuation in the values of the set E of values of the elapsed duration D between the first instant t1 and the second instant t2 includes a difference between:
a current value of the elapsed duration D between the first instant t1 and the second instant t2, determined for a current actuation of the switching device 30; and
an average value Moy of the values of the elapsed duration D between the first instant t1 and the second instant t2 obtained for a predetermined number M of actuations preceding the current actuation of the switching device 30.

The average value Moy can be a sliding average computed from the values corresponding to the actuations preceding the current actuation, and comprising a number of values equal to the predetermined number M of actuations.

According to one embodiment of the detection process, the statistical parameter P representing a fluctuation in the values of the set E of values of the elapsed duration D between the first instant t1 and the second instant t2 comprises a standard deviation of the values of the elapsed duration D between the first instant t1 and the second instant t2 determined for a set of actuations of the switching device 30 carried out under reference conditions corresponding to a new state of the circuit breaker 30.

The set of actuations of the switching device 30 carried out under reference conditions comprises 20 successive actuations of the switching device 30, for example.

The proposed process thus comprises a calibration phase for quantifying the nominal variations in the value of the elapsed duration D between the first instant t1 and the second instant t2 when the switching device 30 is actuated. These nominal variations correspond to the variations observed in a reference state in which the switching device 30 exhibits neither assembly faults nor degradation due to wear. The reference state corresponds to a new state of the switching device 30, for example.

The proposed process comprises a measurement phase in which the variations in the value of the elapsed duration D between the first instant t1 and the second instant t2 are analysed.

The measurement phase follows the calibration phase.
The measurement phase is carried out throughout the operating duration of the switching device 30.

The values acquired under these reference conditions are used to determine the nominal variability of the elapsed duration D between the first instant t1 and the second instant t2. This nominal variability is characterised in this case by the mathematical quantity equal to the standard deviation of the elapsed duration D between the first instant t1 and the second instant t2, computed for all the measurements taken under the reference conditions. This nominal variability is characterised from a predetermined number of values corresponding to a predetermined number of actuations. For example, 20 successive actuations carried out when the switching device 30 is new can be used to characterise the nominal variability of the quantity used to determine degradation of the switching device 30.

FIG. 6 illustrates the values of the duration D between the first instant t1 and the second instant t2, for various actuations of the switching device 30. Part A schematically shows the measurements taken at a first instant t_A. Part B of the FIG. schematically shows the measurements taken at a second instant t_B, which is later than t_A.

The measurement points framed by the frame denoted JO are those taken under reference conditions corresponding to a new state of the switching device 30. In order to simplify the figure, only 7 measurement points have been shown. It can be seen that the dispersion of the values of the quantity D is low.

Reference sign Eco denotes the standard deviation of the values corresponding to the set of actuations of the switching device 30 carried out under reference conditions, and taken into account for the calibration phase.

In part A of FIG. 6, the measurement points framed by the frame denoted J1 are the points used at the instant t_A for the measurement phase. As before, in order to simplify the figure only 10 measurement points of the duration D have been shown.

The value Dₙ, which is determined at the instant t_A, is the current value at the instant t_A, i.e., the most recent value.
The dashed horizontal line indicates the average value moy_A of the values taken into account, i.e., those present in the frame J1.
The arrow denoted e_A illustrates the difference between the current value Dn and the average value moy_A computed in this example from the 10 measurement points preceding the current measurement Dn.

In part B of FIG. 6, the measurement points framed by the frame denoted J2 are the points used at the instant t_B for the measurement phase. As before, 10 measurement points are used in the figure.

The value determined at the instant t_B is the current value at the instant t_B, i.e., the most recent value. Compared with the instant t_A, 4 new measurements have been acquired, and the 4 oldest values in frame J1 are not used at the instant t_B and do not form part of the frame J2.
The dashed horizontal line indicates the average value moy_B of the values taken into account, i.e., those present in the frame J2.
The arrow denoted e_B illustrates the difference between the current value Dₙ₊₄ and the average value moy_B.

More specifically, the statistical parameter P representing a fluctuation in the elapsed duration D between the first instant t1 and the second instant t2 is equal to the ratio of:
the difference between a current value Di of the elapsed duration D between the first instant t1 and the second instant t2 and the average value Moy of the values of the elapsed duration D between the first instant t1 and the second instant t2 obtained for a predetermined number M of actuations preceding the current actuation; and
the standard deviation Ec of the values of the elapsed duration D between the first instant t1 and the second instant t2 determined for a set of actuations of the switching device 30 carried out under reference conditions corresponding to a new state of the switching device 30.

The proposed statistical parameter P allows reliable detection of any degradation of the unlocking member 8 of the control mechanism 4 of the switching device 30, while being simple to implement. In particular, the necessary computations can be easily carried out in real time, which allows rapid degradation detection.

The statistical parameter P representing a fluctuation in the elapsed duration D between the first instant t1 and the second instant t2 is thus equal to:

$$\\ \begin{matrix}P ( i ) = \frac{{D}_{i} - \frac{{\sum }_{j = i - M}^{j = i - 1} {D}_{j}}{M}}{\sqrt{{\sum }_{j = 1}^{N} {( \frac{{D}_{j} - \frac{{\sum }_{j = 1}^{j = N} {D}_{j}}{K}}{K} )}^{2}}} & [ Math . 1 ]\end{matrix}$$

With Dᵢ being the determined value of the duration D for an actuation of rank i, P(i) being the computed value of the statistical parameter P for the actuation of rank i, M being the number of actuations taken into account to determine an average value, K being the number of actuations carried out under reference conditions corresponding to a new state of the switching device 30.

The computation completed for the statistical parameter P allows a conclusion to be provided concerning the state of the control mechanism 4.

Degradation of the unlocking member 8 is determined when the absolute value of the statistical parameter P representing a fluctuation in the elapsed duration D between the first instant t1 and the second instant t2 is greater than a first positive predetermined threshold S1.

The value selected for the first predetermined threshold S1 allows the sensitivity of the proposed detection process to be adjusted.

The first predetermined threshold S1 ranges between 2 and 3, for example.

According to one embodiment of the detection process, the degradation of the unlocking member 8 is classified as a first type of degradation, called minor degradation, when the absolute value of the statistical parameter P representing a fluctuation in the elapsed duration D between the first instant t1 and the second instant t2 is greater than a first positive predetermined threshold S1 and less than a second positive predetermined threshold S2.

The second positive predetermined threshold S2 ranges between 4 and 5, for example.

The degradation of the unlocking member 8 is classified as a second type of degradation, called major degradation, when the absolute value of the parameter P representing a fluctuation in the elapsed duration D between the first instant t1 and the second instant t2 is greater than the second positive predetermined threshold S2.

The statistical parameter P that is used thus allows the degradation to be quantified, and not merely the presence or absence of degradation.

The detection process can include a step of transmitting a warning signal in the event that degradation of the unlocking member 8 has been determined.

The transmitted warning signal allows users to schedule and to carry out a maintenance or replacement operation for the switching device 30.

The warning signal can be, for example, a code stored in an electronic control unit.

As an alternative embodiment or additionally, the warning signal can involve turning on an indicator light.
As a further alternative embodiment or additionally, the warning signal can involve displaying a message on a control screen.
Of course, other types of warning are possible.

A warning signal is not transmitted when no degradation has been determined. In other words, no warning is transmitted when the proposed process indicates that the control mechanism 4 is degradation free.

1. A process for detecting degradation of a switching device comprising:
an electrical contact movable between a closed position of an electrical circuit and an open position of the electrical circuit;
a control mechanism comprising:
a driving element configured to displace the mobile electrical contact so as to open an electrical circuit;
an elastic member connected to the driving element;
an unlocking member configured to transition from a locking position, in which the elastic member is held in a tensioned state, to a release position, in which the elastic member is free to slacken, so as to displace the electrical contact from the closed position to the open position of the electrical circuit, or from the open position to the closed position;
an actuator configured to displace the unlocking member from the locking position to the release position, the process comprising the following steps:
(i) commanding the actuator so as to displace the unlocking member from the locking position to the release position;
(ii) determining a first instant corresponding to a predetermined position of the unlocking member;
(iii) determining a second instant corresponding to a predetermined position of the driving element;
(iv) determining an elapsed duration between the first instant and the second instant;
(v) iterating steps (i) to (iii) for a set of successive commands of the actuator, so as to obtain a set of values of the elapsed duration between the first instant and the second instant;
(vi) determining degradation of the unlocking member of the switching device from the change in the values of the set during successive commands of the actuator.

2. The detection process according to claim 1, wherein the actuator is an electromagnetic actuator, and wherein the process comprises the following sub-steps:
measuring a current flowing through the electromagnetic actuator when the switching device is actuated;
determining the first instant corresponding to a predetermined position of the unlocking member from the temporal variations in the measured current.

3. The detection process according to claim 2, wherein the electromagnetic actuator comprises a control coil and a magnetic core configured to displace under the action of a magnetic field created by a flow of electric current through the control coil,
and wherein the predetermined position of the unlocking member corresponding to the first instant is a position of maximum displacement of the magnetic core.

4. The detection process according to claim 2, wherein the first instant corresponding to a predetermined position of the unlocking member is an instant corresponding to a local minimum value of the electric current flowing through the electromagnetic actuator.

5. The detection process according to claim 1, wherein the actuator comprises a push-button that can be manually activated by an operator and wherein the unlocking member comprises a position indicator, wherein the process comprises the following sub-steps:
measuring an electrical signal from the position indicator;
determining the first instant corresponding to a predetermined position of the unlocking member from temporal variations in the electrical signal from the position indicator.

6. The detection process according to claim 1, wherein the predetermined position of the driving element corresponding to the second instant is an intermediate displacement position of the driving element, with the intermediate displacement position lying between a first end position, in which the mobile electrical contact is in the closed position, and a second end position, in which the mobile electrical contact is in the open position.

7. The detection process according to claim 6, wherein a displacement stroke of the driving element between the first end position and the predetermined position corresponding to the second instant ranges between 5% and 15% of a total displacement stroke of the driving element.

8. The detection process according to claim 1, comprising the following sub-steps:
measuring a position of the driving element when the switching device is actuated;
determining the second instant corresponding to the predetermined position of the driving element from the measured position of the driving element.

9. The detection process according to claim 1, wherein:
the control mechanism comprises a position sensor configured to detect a magnetic field;
the driving element comprises a plurality of magnetic elements configured to successively pass in front of the position sensor during a displacement stroke of the driving element.

10. The detection process according to claim 1, comprising the following sub-step:
computing a value of a statistical parameter representing a fluctuation in the values of the set of values of the elapsed duration between the first instant and the second instant;
determining degradation of the unlocking member from the computed value of the statistical parameter.

11. The detection process according to claim 10, wherein the statistical parameter representing a fluctuation in the values of the set of values of the elapsed duration between the first instant and the second instant includes a difference between:
a current value of the elapsed duration between the first instant and the second instant, determined for a current actuation of the switching device; and
an average value of the values of the elapsed duration between the first instant and the second instant obtained for a predetermined number of actuations preceding the current actuation of the switching device.

12. The detection process according to claim 10, wherein the statistical parameter representing a fluctuation in the values of the set of values of the elapsed duration between the first instant and the second instant comprises a standard deviation of the values of the elapsed duration between the first instant and the second instant determined for a set of actuations of the switching device carried out under reference conditions corresponding to a new state of the circuit breaker.

13. The detection process according to claim 10, wherein the statistical parameter representing a fluctuation in the elapsed duration between the first instant and the second instant is equal to the ratio of:
the difference between a current value of the elapsed duration between the first instant and the second instant and the average value of the values of the elapsed duration between the first instant and the second instant obtained for a predetermined number of actuations preceding the current actuation; and
the standard deviation of the values of the elapsed duration between the first instant and the second instant determined for a set of actuations of the switching device carried out under reference conditions corresponding to a new state of the switching device.

14. The detection process according to claim 10, wherein the statistical parameter representing a fluctuation in the elapsed duration between the first instant and the second instant is equal to:
$$\\ P ( i ) = \frac{{D}_{i} - \frac{{\sum }_{j = i - M}^{j = i - 1} {D}_{j}}{20}}{\sqrt{{\sum }_{j = 1}^{N} {( \frac{{D}_{j} - \frac{{\sum }_{j = 1}^{j = N} {D}_{j}}{N}}{N} )}^{2}}}$$

15. The detection process according to claim 10, wherein degradation of the unlocking member is determined when the absolute value of the statistical parameter representing a fluctuation in the elapsed duration between the first instant and the second instant is greater than a first positive predetermined threshold.

16. The detection process according to claim 15, wherein:
the degradation of the unlocking member is classified as a first type of degradation, called minor degradation, when the absolute value of the statistical parameter representing a fluctuation in the elapsed duration between the first instant and the second instant is greater than a first positive predetermined threshold and less than a second positive predetermined threshold; and wherein:
the degradation of the unlocking member is classified as a second type of degradation, called major degradation, when the absolute value of the statistical parameter representing a fluctuation in the elapsed duration between the first instant and the second instant is greater than the second positive predetermined threshold.

17. The detection process according to claim 15, comprising a step of transmitting a warning signal in the event that degradation of the unlocking member has been determined.

18. A switching device comprising:
an electrical contact movable between a closed position of an electrical circuit and an open position of the electrical circuit;
a control mechanism comprising:
a driving element configured to displace the mobile electrical contact so as to open an electrical circuit;
an elastic member connected to the driving element;
an unlocking member configured to transition from a locking position, in which the elastic member is held in a tensioned state, to a release position, in which the elastic member is free to slacken, so as to displace the electrical contact from the closed position to the open position of the electrical circuit;
an actuator configured to displace the unlocking member from the locking position to the release position;
an electronic control unit configured to implement the degradation detection process according to claim 1, the switching device being a circuit breaker, or a switch, or an isolator.
